(19) United States
(12) Patent Application Publication
(10) Pub. No.: US 2012/0155191 A1
(43) Pub. Date: Jun. 21, 2012

(54) SEMICONDUCTOR MEMORY DEVICE

(76) Inventors: Shoichiro Hashimoto, Tokyo (JP); Tokumasa Hara, Kawasaki-shi (JP)

(21) Appl. No.: 13/239,480

(22) Filed: Sep. 22, 2011

(30) Foreign Application Priority Data
Dec. 17, 2010 (JP) 2010-281386

(51) Int. Cl. G11C 7/10

(52) U.S. Cl. 365/189.05

(57) ABSTRACT

According to one embodiment, a semiconductor memory device includes a first memory configured to receive a first clock and including a first buffer configured to perform a data input operation and a data output operation, a second memory including a second buffer configured to perform a data input operation and a data output operation, and a data bus configured to connect the first buffer and the second buffer. The first memory transfers a second clock to the second memory using the first clock. The first buffer transfers data to the second memory in response to the first clock. The second buffer receives the data from the first buffer in response to the second clock.

### CROSS-REFERENCE TO RELATED APPLICATIONS

This application is based upon and claims the benefit of priority from prior Japanese Patent Application No. 2010-281386, filed Dec. 17, 2010, the entire contents of which are incorporated herein by reference.

### FIELD

Embodiments described herein relate generally to a semiconductor memory device.

### BACKGROUND

A system LSI that integrates memories of different types on one chip has been developed. Take an example of a semiconductor memory device including a first memory (for example, a NAND flash memory), a second memory (for example, an SRAM), and an ECC circuit arranged between the NAND flash memory and the SRAM. The NAND flash memory, the SRAM, and the ECC circuit exchange data using a reference clock.

When the NAND flash memory and the SRAM transfer data via the ECC circuit, there exist an interconnect delay of the clock path, a delay required for data output in the memory, an interconnect delay of the data path, and the like. That is, the semiconductor memory device includes a plurality of delay elements. For this reason, for example, when data is transferred between the NAND flash memory and the ECC circuit, it is difficult to ensure the setup and hold times upon data reception. This makes it difficult to accurately transfer data between the NAND flash memory and the SRAM.

### BRIEF DESCRIPTION OF THE DRAWINGS

FIG. 1 is a block diagram showing the arrangement of a memory system 1 according to the first embodiment;

FIG. 2 is a circuit diagram showing the arrangement of a block BLK;

FIG. 3 is a timing chart showing a data transfer operation from a NAND flash memory 10 to an ECC circuit 30;

FIG. 4 is a timing chart illustrating the logic of enable signals in a load operation;

FIG. 5 is a timing chart showing a data transfer operation from the ECC circuit 30 to an SRAM 20;

FIG. 6 is a timing chart illustrating the logic of enable signals in a program operation; and

FIG. 7 is a block diagram showing the arrangement of a memory system 1 according to the second embodiment.

### DETAILED DESCRIPTION

In general, according to one embodiment, there is provided a semiconductor memory device comprising:

a first memory configured to receive a first clock and including a first buffer configured to perform a data input operation and a data output operation;

a second memory including a second buffer configured to perform a data input operation and a data output operation; and

a data bus configured to connect the first buffer and the second buffer,

wherein the first memory transfers a second clock to the second memory using the first clock,

the first buffer transfers data to the second memory in response to the first clock, and

the second buffer receives the data from the first buffer in response to the second clock.

The embodiments will be described hereinafter with reference to the accompanying drawings. In the description which follows, the same or functionally equivalent elements are denoted by the same reference numerals, to thereby simplify the description.

### First Embodiment

An example of a semiconductor memory device in which a plurality of kinds of memories are integrated on one chip is OneNAND®. A OneNAND device is formed by integrating a NAND flash memory serving as a main memory unit and a static random access memory (SRAM) serving as a buffer unit on one chip. In this embodiment, the OneNAND device will be exemplified as the semiconductor memory device (memory system) in which a plurality of kinds of memories are integrated on one chip.

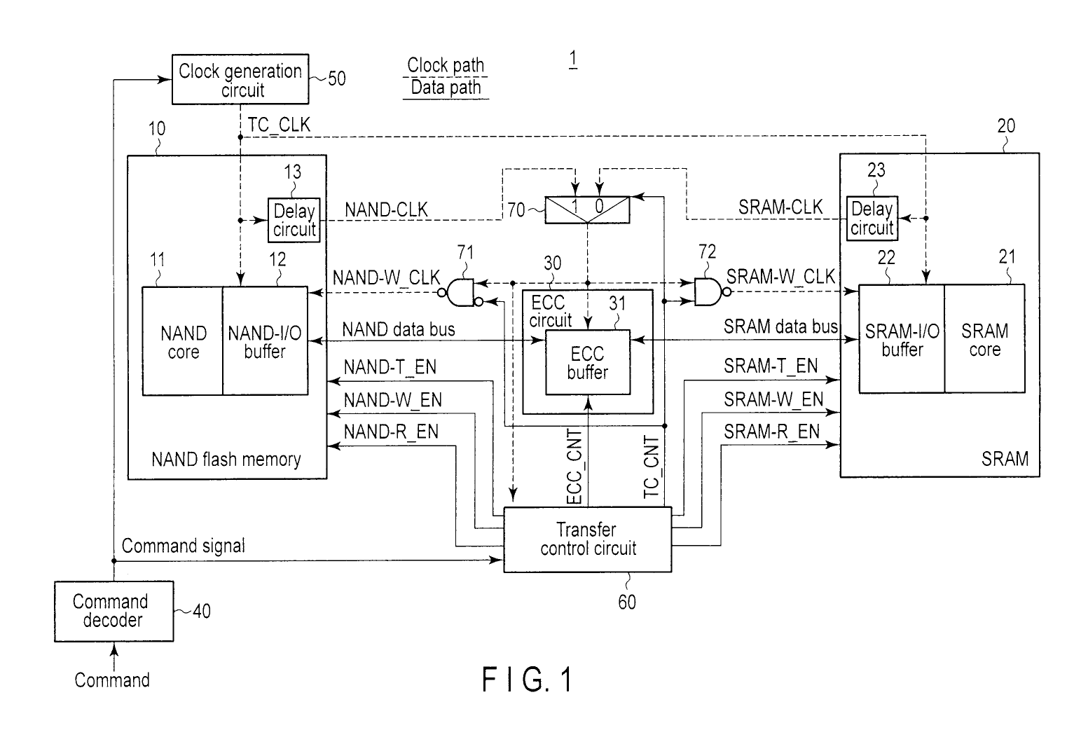

FIG. 1 is a block diagram showing the arrangement of a memory system 1 according to the first embodiment. The memory system 1 comprises a NAND flash memory 10, an SRAM 20, an error checking and correcting (ECC) circuit 30, a command decoder 40, a clock generation circuit 50, a transfer control circuit 60, a selector 70, and NAND gates 71 and 72.

In the memory system 1, the NAND flash memory 10 serves as a main memory unit, and the SRAM 20 serves as a memory buffer. Hence, to read data from the NAND flash memory 10 to the outside (for example, host device), first, data read from the NAND flash memory 10 is stored in the SRAM 20. After that, the data in the SRAM 20 is output to the host device via an interface (not shown). On the other hand, to store data in the NAND flash memory 10, first, data input from the host device to the memory system 1 is stored in the SRAM 20 via the interface. After that, the data in the SRAM 20 is written to the NAND flash memory 10.

In the following description, the operation from data read from the NAND flash memory 10 until transfer to the SRAM 20 will be referred to as “load”. The operation of writing the data in the SRAM 20 to the NAND flash memory 10 will be referred to as “program”. The command decoder 40 receives a command from the host device or the like via an input/output pad (I/O pad). The command decoder 40 interprets the command and outputs a command signal. The command signal is sent to the clock generation circuit 50 and the transfer control circuit 60.

The clock generation circuit 50 generates a transfer control clock TC_CLK in accordance with the command signal. The transfer control clock TC_CLK is sent to the NAND flash memory 10 and the SRAM 20. The transfer control clock TC_CLK is used for data output processing of the NAND flash memory 10 and the SRAM 20.

The NAND flash memory 10 comprises a NAND core 11, a NAND input/output buffer (NAND-I/O buffer) 12, and a delay circuit 13. Delay circuit 13 receives the transfer control clock TC_CLK and outputs a NAND clock NAND_CLK by delaying the transfer control clock TC_CLK by a predetermined time. The NAND clock NAND_CLK is sent to the selector 70.

The NAND-I/O buffer 12 performs data input/output processing of the NAND flash memory 10. To perform the data input/output processing, the NAND-I/O buffer 12 receives the transfer control clock TC_CLK, a NAND write clock NAND-W_CLK, and a NAND transfer enable signal NAND-T_EN, and is connected to the ECC circuit 30 via the NAND data bus. In the load operation, the NAND-I/O buffer 12 temporarily stores (holds) data read from the NAND core 11, and sends the data to the ECC circuit 30 in response to clock TC_CLK. In the program operation, the NAND-I/O buffer 12 receives data transferred from the ECC circuit 30 in response to clock NAND-W_CLK, and temporarily stores the data.

The NAND core 11 includes a NAND cell array, a row decoder that applies voltages to word lines, and a page buffer that writes data to the NAND cell array or reads data from the NAND cell array via bit lines.

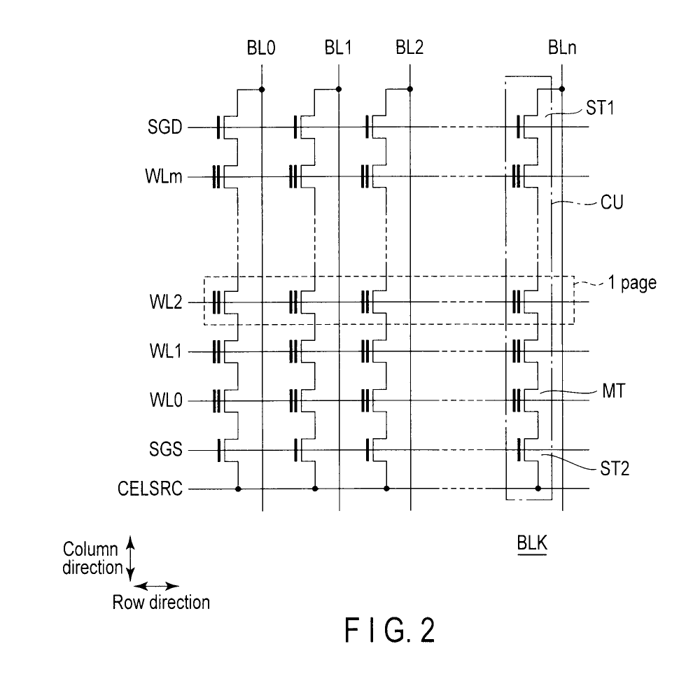

The NAND cell array includes a plurality of blocks BLK each serving as a data erase unit. FIG. 2 is a circuit diagram showing the arrangement of one block BLK.

The block BLK includes a plurality of memory cell units CU. Each memory cell unit CU includes a plurality of memory cell transistors MT and two select transistors ST1 and ST2. The memory cell transistor MT has a stacked gate structure including a charge storage layer (for example, floating gate electrode) formed on a gate insulating film on the semiconductor substrate, and a control gate electrode formed on a gate insulating film on the charge storage layer. The memory cell transistor MT may have not the floating gate structure but a metal-oxide-nitride-oxide-silicon (MONOS) structure using a method of causing an insulating film (for example, a nitride film) serving as a charge storage layer to trap electrons.

The current paths of the memory cell transistors MT adjacent to each other in one memory cell unit CU are connected in series. More specifically, (m+1) memory cell transistors MT are connected in series in the column direction so that adjacent transistors share the diffusion region (the source region or drain region). The drain on the side of one end of the serially connected memory cell transistors MT is connected to the source of select transistor ST1. The source on the other end side is connected to the drain of select transistor ST2.

The control gate electrodes of the memory cell transistors MT on the same row are commonly connected to one of a plurality of word lines WL0 to WLm. The gate electrodes of select transistors ST1 or ST2 on the same row are commonly connected to a select gate line SGD or SGS. The drain of each select transistor ST1 is connected to one of a plurality of bit lines BL0 to BLn. The sources of select transistors ST2 are commonly connected to a source line CELSRC.

A plurality of memory cell transistors MT connected to the same word line WL constitute a page. Data write and read are executed at once for the memory cell transistors MT in one page.

A bit line BL commonly connects the drains of select transistors ST1 between blocks. That is, the memory cell units CU on the same column in a plurality of blocks are connected to the same bit line BL.

Each memory cell transistor MT can store one-bit data in accordance with a change in the threshold voltage based on, for example, the amount of electrons injected into the floating gate electrode. The threshold voltage may be controlled more finely to store data of two or more bits in each memory cell transistor MT.

The SRAM 20 comprises an SRAM core 21, an SRAM input/output buffer (SRAM-I/O buffer) 22, and a delay circuit 23. Delay circuit 23 receives the transfer control clock TC_CLK and outputs an SRAM clock SRAM-CLK by delaying the transfer control clock TC_CLK by a predetermined time.

The SRAM-I/O buffer 22 performs data input/output processing of the SRAM 20. To perform the data input/output processing, the SRAM-I/O buffer 22 receives the transfer control clock TC_CLK, an SRAM write clock SRAM-W_CLK, and an SRAM transfer enable signal SRAM-T_EN, and is connected to the ECC circuit 30 via the SRAM data bus. In the program operation, the SRAM-I/O buffer 22 temporarily stores data read from the SRAM core 21, and sends the data to the ECC circuit 30 in response to the transfer control clock TC_CLK. In the load operation, the SRAM-I/O buffer 22 receives data transferred from the ECC circuit 30 in response to write clock SRAM-W_CLK, and temporarily stores the data.

The SRAM core 21 includes an SRAM cell array, a row decoder, and a sense amplifier. The SRAM cell array comprises a plurality of memory cells (SRAM cells) arranged in a matrix at the intersections between a plurality of word lines and a plurality of bit line pairs.

The ECC circuit 30 comprises an ECC buffer 31 that temporarily stores data for ECC processing. In the program operation, the ECC circuit 30 generates a parity signal using data input from the SRAM 20 to the ECC buffer 31. In the load operation, the ECC circuit 30 performs error correction using data (including a parity signal) input from the NAND flash memory 10 to the ECC buffer 31. The ECC buffer 31 performs data input/output processing in response to a clock sent from the selector 70.

The transfer control circuit 60 controls data transfer processing between the NAND flash memory 10 and the ECC circuit 30 and between the SRAM 20 and the ECC circuit 30 based on a command signal. For the data transfer processing, the transfer control circuit 60 generates an ECC control signal ECC_CNT, a transfer clock control signal TC_CNT, a NAND write enable signal NAND-W_EN, a NAND read enable signal NAND-R_EN, the NAND transfer enable signal NAND-T_EN, an SRAM write enable signal SRAM-W_EN, an SRAM read enable signal SRAM-R_EN, and the SRAM transfer enable signal SRAM-T_EN. The transfer control circuit 60 outputs various kinds of control signals in response to a clock sent from the selector 70.

The ECC control signal ECC_CNT controls data to be received by the ECC circuit 30 (more specifically, ECC buffer 31). The ECC control signal ECC_CNT goes high when the ECC buffer 31 receives data. The ECC control signal ECC_CNT is sent to the ECC circuit 30.

The transfer clock control signal TC_CNT switches between the NAND clock NAND_CLK and the SRAM clock SRAM_CLK. The transfer clock control signal TC_CNT goes high in the load operation, and goes low in the program operation. The transfer clock control signal TC_CNT is sent to the selector 70 and NAND gates 71 and 72.

The NAND write enable signal NAND-W_EN enables the write path of the NAND flash memory 10, and also causes the NAND flash memory 10 to select the NAND write clock NAND-W_CLK in the program operation. The NAND read enable signal NAND-R_EN enables the read path of the NAND flash memory 10, and also causes the NAND flash memory 10 to select the transfer control clock TC_CLK in the load operation. The NAND transfer enable signal NAND-T_EN activates the data transfer operation of the NAND flash memory 10. The NAND flash memory 10 performs data transfer with respect to the SRAM 20 when enable signal NAND-T_EN is high.

The SRAM write enable signal SRAM-W_EN enables the write path of the SRAM 20, and also causes the SRAM 20 to select the SRAM write clock SRAM-W_CLK in the load operation. The SRAM read enable signal SRAM-R_EN enables the read path of the SRAM 20, and also causes the SRAM 20 to select the transfer control clock TC_CLK in the program operation. The SRAM transfer enable signal SRAM-T_EN activates the data transfer operation of the SRAM 20. The SRAM 20 performs data transfer with respect to the NAND flash memory 10 when enable signal SRAM-T_EN is high.

The first input terminal of the selector 70 receives clock NAND_CLK from delay circuit 13. The second input terminal of the selector 70 receives clock SRAM_CLK from delay circuit 23. The control terminal of the selector 70 receives the control signal TC_CNT from the transfer control circuit 60. The selector 70 outputs clock NAND_CLK when the control signal TC_CNT is high, and outputs clock SRAM_CLK when the control signal TC_CNT is low. The clock output from the selector 70 is sent to the first input terminals of NAND gates 71 and 72, the ECC buffer 31, and the transfer control circuit 60.

The second input terminal (active low terminal) of NAND gate 71 receives the control signal TC_CNT from the transfer control circuit 60. When the control signal TC_CNT is low, NAND gate 71 outputs write clock NAND-W_CLK by inverting clock SRAM_CLK sent from the selector 70.

The second input terminal of NAND gate 72 receives the control signal TC_CNT from the transfer control circuit 60. When the control signal TC_CNT is high, NAND gate 72 outputs write clock SRAM-W_CLK by inverting clock NAND_CLK sent from the selector 70.

### (Operation)

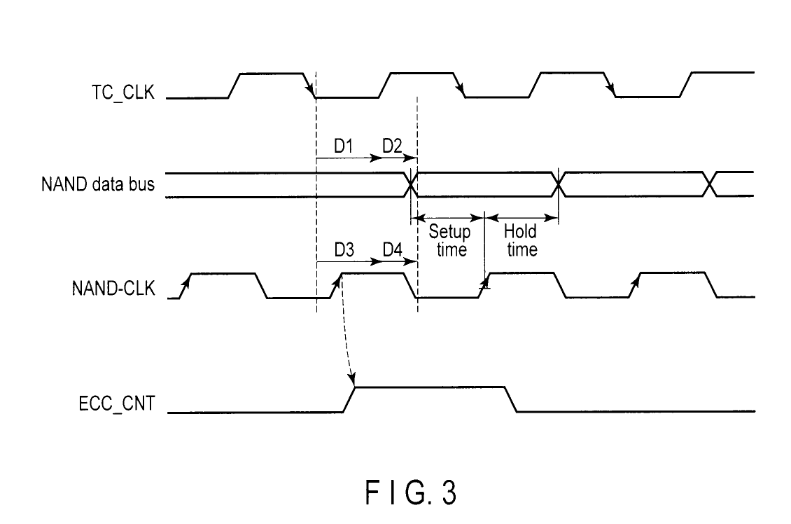

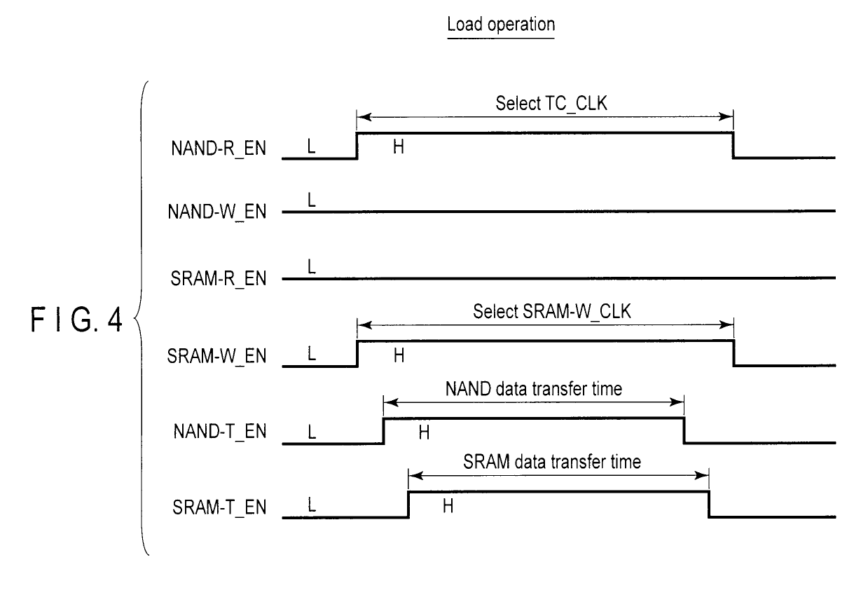

The operation of the memory system 1 having the above-described arrangement will be described next. The load operation, that is, the data transfer operation from the NAND flash memory 10 to the SRAM 20 will be described below as an example. FIG. 3 is a timing chart showing the data transfer operation from the NAND flash memory 10 to the ECC circuit 30 in the load operation. FIG. 4 is a timing chart illustrating the logic of the enable signals in the load operation.

When the load operation starts based on the command signal, the NAND flash memory 10 receives the transfer control clock TC_CLK from the clock generation circuit 50. The NAND core 11 executes the data read operation. Data read from the NAND core 11 is sent to the NAND-I/O buffer 12 and held therein.

The transfer control circuit 60 makes read enable signal NAND-R_EN high. Upon receiving read enable signal NAND-R_EN, the NAND flash memory 10 executes the data transfer operation using the transfer control clock TC_CLK from then on.

Subsequently, the transfer control circuit 60 makes transfer enable signal NAND-T_EN high. Upon receiving transfer enable signal NAND-T_EN, the NAND-I/O buffer 12 outputs the read data to the NAND data bus in response to the transfer control clock TC_CLK. The read data output to the NAND data bus is input to the ECC circuit 30. As shown in FIG. 3, the data read from the NAND core 11 is input to the ECC circuit 30 with a delay time D1 required for data output in the NAND flash memory 10 and a delay time D2 by the interconnect delay of the NAND data bus.

On the other hand, the transfer control clock TC_CLK input to the NAND flash memory 10 is also input to delay circuit 13. Delay circuit 13 delays the transfer control clock TC_CLK by the same delay time as delay time D1 required for data output in the NAND flash memory 10. To implement delay time D1, delay circuit 13 includes the same circuits or interconnections as those of the data read path in the NAND flash memory 10. Delay circuit 13 outputs the NAND clock NAND_CLK. The NAND clock NAND_CLK is input to the selector 70 via the clock path.

In the load operation, the transfer control circuit 60 supplies the high transfer clock control signal TC_CNT to the selector 70 and NAND gates 71 and 72. Hence, the selector 70 outputs the NAND clock NAND_CLK. The NAND clock NAND_CLK output from the selector 70 is input to the ECC circuit 30, the transfer control circuit 60, and NAND gates 71 and 72. As shown in FIG. 3, the transfer control clock TC_CLK is input to the ECC circuit 30 and the like as the NAND clock NAND_CLK with a delay time D3 by delay circuit 13 and a delay time D4 by the interconnect delay of the clock path.

Delay time D3 is almost equal to delay time D1. Delay time D4 is almost equal to delay time D2 because the clock path of the NAND clock NAND_CLK has almost the same length as that of the NAND data bus. Since the delay times of the clock and data can be almost equal, the ECC circuit 30 can ensure the margin of the setup and hold times.

The transfer control circuit 60 sends the ECC control signal ECC_CNT to the ECC buffer 31 in response to the NAND clock NAND_CLK. When the ECC control signal ECC_CNT is high, the ECC buffer 31 receives the read data from the NAND data bus in response to the NAND clock NAND_CLK. The ECC circuit 30 executes error correction processing using the NAND clock NAND_CLK. In this case as well, since the transfer control circuit 60 outputs the ECC control signal ECC_CNT using the same clock (NAND clock NAND_CLK) as that of the ECC circuit 30, the ECC circuit 30 can ensure the margin of the setup and hold times.

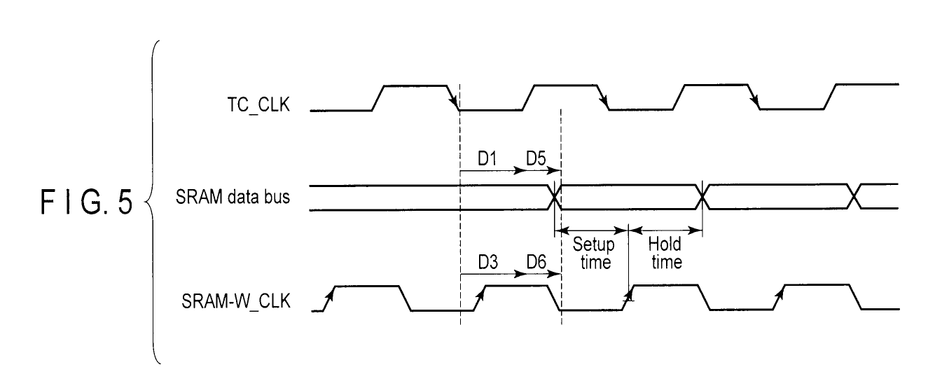

Next, data transfer from the ECC circuit 30 to the SRAM 20 is performed. FIG. 5 is a timing chart showing the data transfer operation from the ECC circuit 30 to the SRAM 20 in the load operation.

The ECC buffer 31 outputs data to the SRAM data bus in response to the NAND clock NAND_CLK. The data output to the SRAM data bus is input to the SRAM-I/O buffer 22. As shown in FIG. 5, the data read from the NAND core 11 is input to the SRAM-I/O buffer 22 with delay time D1 required for data output in the NAND flash memory 10 and a delay time D5 by the interconnect delay of the data bus (the NAND data bus and the SRAM data bus).

The NAND clock NAND_CLK output from the selector 70 is input to the SRAM-I/O buffer 22 as the SRAM write clock SRAM-W_CLK via NAND gate 72. As shown in FIG. 5, the transfer control clock TC_CLK is input to the SRAM-I/O buffer 22 as clock SRAM-W_CLK with delay time D3 by delay circuit 13 and a delay time D6 by the interconnect delay of the clock path. Delay time D6 is almost equal to delay time D5 because the clock path and the data path between the NAND flash memory 10 and the SRAM 20 have almost the same length. Since the delay times of the clock and data can almost be equal, the SRAM-I/O buffer 22 can ensure the margin of the setup and hold times.

The transfer control circuit 60 makes write enable signal SRAM-W_EN high at the same timing as that of read enable signal NAND-R_EN. Then, the transfer control circuit 60 makes transfer enable signal SRAM-T_EN high. Upon receiving write enable signal SRAM-W_EN and transfer enable signal SRAM-T_EN, the SRAM 20 executes the data transfer operation and the data write operation using clock SRAM-W_CLK. More specifically, the SRAM-I/O buffer 22 receives the data from the SRAM data bus in response to clock SRAM-W_CLK and holds it. The data held by the SRAM-I/O buffer 22 is written to the SRAM core 21.

Note that the same functions and effects as those of the above-described load operation can be obtained in the program operation, that is, the data transfer operation from the SRAM 20 to the NAND flash memory 10 as well. The directions of clock and data flows in the program operation are reverse to those in the load operation.

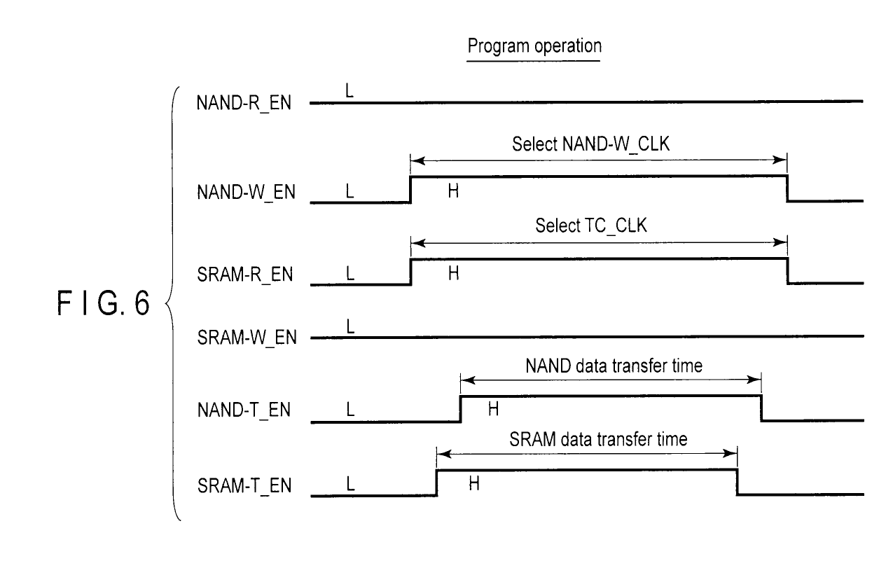

FIG. 6 is a timing chart illustrating the logic of the enable signals in the program operation. In the program operation, the transfer control circuit 60 makes read enable signal SRAM-R_EN and write enable signal NAND-W_EN high. Upon receiving read enable signal SRAM-R_EN, the SRAM 20 executes the data transfer operation using the transfer control clock TC_CLK.

In the program operation, delay circuit 23 that includes the same circuits or interconnections as those of the data read path in the SRAM 20 outputs the SRAM clock SRAM_CLK by delaying the transfer control clock TC_CLK by the same delay time as the delay time required for data output in the SRAM 20. The ECC circuit 30 and the transfer control circuit 60 operate using clock SRAM_CLK. Upon receiving write enable signal NAND-W_EN, the NAND flash memory 10 executes the data transfer operation using the NAND write clock NAND-W_CLK generated from clock SRAM_CLK.

### (Effects)

As described above in detail, according to the first embodiment, in the data transfer operation (load operation) of “NAND flash memory 10→ECC circuit 30→SRAM 20”, the NAND flash memory 10 serving as the data transfer source supplies clock NAND_CLK to the ECC circuit 30, the SRAM 20, and the transfer control circuit 60. The memory system 1 comprises delay circuit 13 that delays the transfer control clock TC_CLK by the same delay time as delay time D1 required for data output in the NAND flash memory 10. Delay circuit 13 outputs clock NAND_CLK.

Similarly, in the data transfer operation (program operation) of “SRAM 20→ECC circuit 30→NAND flash memory 10”, the SRAM 20 serving as the data transfer source supplies clock SRAM_CLK to the ECC circuit 30, the NAND flash memory 10, and the transfer control circuit 60. The memory system 1 comprises delay circuit 23 that delays the transfer control clock TC_CLK by the same delay time as the delay time required for data output in the SRAM 20. Delay circuit 23 outputs clock SRAM_CLK.

Hence, according to the first embodiment, since the delay times of the data and clock input to the ECC buffer 31 are almost the same, the margin of the setup and hold times can be ensured when the ECC buffer 31 receives data. In addition, since the transfer control circuit 60 operates using the same clock as that of the ECC buffer 31, the margin of the setup and hold times can be ensured even for the control signal from the transfer control circuit 60. This allows the memory system 1 to implement accurate data transfer.

In the load operation, since the delay times of the data and clock input to the SRAM 20 are almost the same, the margin of the setup and hold times can be ensured when the SRAM-I/O buffer 22 receives data. The same effects can also be obtained for the program operation.

The transfer control circuit 60 supplies an enable signal for switching between clock TC_CLK and clock NAND-W_CLK to the NAND flash memory 10. This allows the NAND flash memory 10 to operate by selecting an optimum clock. The same effects can also be obtained for the SRAM 20.

### Second Embodiment

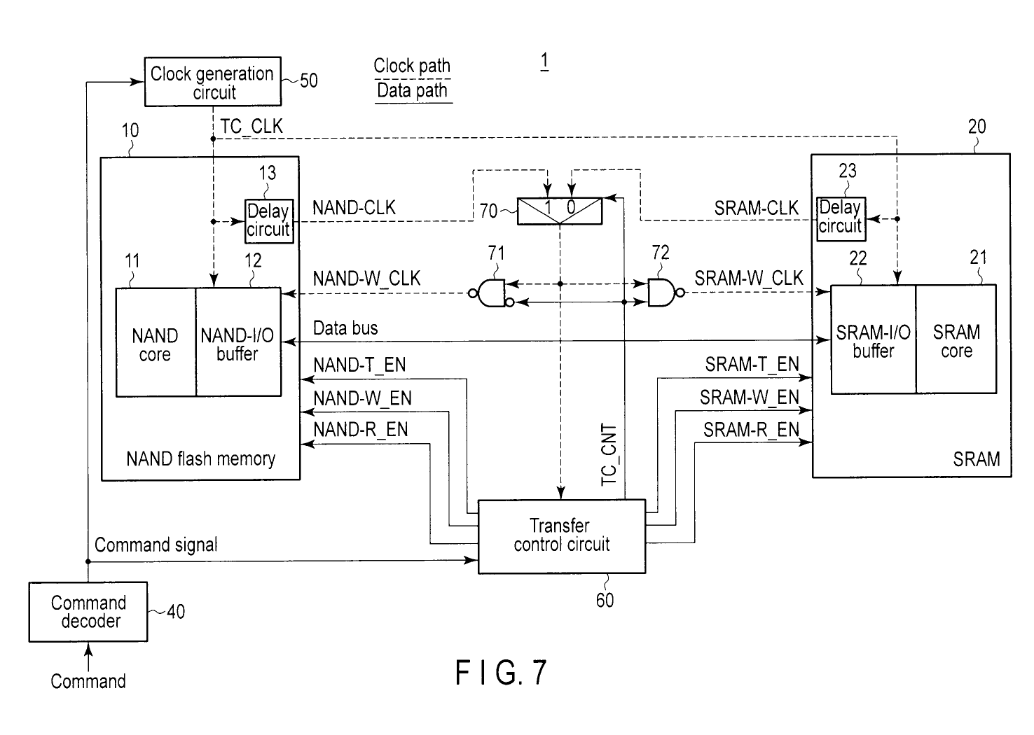

Data transfer may be performed directly between the NAND flash memory 10 and the SRAM 20 without interposing the ECC circuit 30. FIG. 7 is a block diagram showing the arrangement of a memory system 1 according to the second embodiment. A NAND flash memory 10 and an SRAM 20 are directly connected by a data bus. That is, in the second embodiment, the ECC circuit 30 in FIG. 1 is omitted. The remaining components are the same as in FIG. 1.

The data transfer operation from the NAND flash memory 10 to the SRAM 20 will be described next. The timing chart is the same as FIG. 5. Note that the SRAM data bus in FIG. 5 is replaced with the data bus.

When the load operation starts based on the command signal, the NAND flash memory 10 receives a transfer control clock TC_CLK from a clock generation circuit 50. A NAND core 11 executes the data read operation. Data read from the NAND core 11 is sent to a NAND-I/O buffer 12 and held therein.

A transfer control circuit 60 makes a read enable signal NAND-R_EN high. Upon receiving read enable signal NAND-R_EN, the NAND flash memory 10 executes the data transfer operation using the transfer control clock TC_CLK from then on.

Subsequently, the transfer control circuit 60 makes a transfer enable signal NAND-T_EN high. Upon receiving transfer enable signal NAND-T_EN, the NAND-I/O buffer 12 outputs the read data to the data bus in response to the transfer control clock TC_CLK. The read data output to the data bus is input to an SRAM-I/O buffer 22. As shown in FIG. 5, the data read from the NAND core 11 is input to the SRAM-I/O buffer 22 with delay times D1 and D5.

On the other hand, the transfer control clock TC_CLK input to the NAND flash memory 10 is input to the SRAM-I/O buffer 22 as an SRAM write clock SRAM-W_CLK via a delay circuit 13, a selector 70, and a NAND gate 72. As shown in FIG. 5, the transfer control clock TC_CLK is input to the SRAM-I/O buffer 22 as clock SRAM-W_CLK with delay times D3 and D6.

The clock path and the data path between the NAND flash memory 10 and the SRAM 20 have almost the same length. Hence, since the delay times of the clock and data can almost be equal, the SRAM-I/O buffer 22 can ensure the margin of the setup and hold times.

The transfer control circuit 60 makes a write enable signal SRAM-W_EN high at the same timing as that of enable signal NAND-R_EN. Then, the transfer control circuit 60 makes a transfer enable signal SRAM-T_EN high. Upon receiving write enable signal SRAM-W_EN and transfer enable signal SRAM-T_EN, the SRAM 20 executes the data transfer operation and the data write operation using clock SRAM-W_CLK. More specifically, the SRAM-I/O buffer 22 receives the data from the data bus in response to clock SRAM-W_CLK and holds it. The data held by the SRAM-I/O buffer 22 is written to an SRAM core 21.

Note that the same functions and effects as those of the above-described operation can be obtained in the data transfer operation from the SRAM 20 to the NAND flash memory 10 as well. The clock switching operation using the enable signals is also the same as in the first embodiment.

As described above in detail, according to the second embodiment, even in the data transfer operation between the NAND flash memory 10 and the SRAM 20, the margin of the setup and hold times can be ensured when the NAND-I/O buffer 12 or the SRAM-I/O buffer 22 receives data. The remaining effects are the same as in the first embodiment.

Note that in the above embodiments, data transfer between the NAND flash memory, the ECC circuit, and the SRAM has been described. However, the embodiments are not limited to this and are also widely applicable to data transfer between two or more circuit modules other than memories and an ECC circuit.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first memory configured to receive a first clock and including a first buffer configured to perform a data input operation and a data output operation;
a second memory including a second buffer configured to perform a data input operation and a data output operation; and
a data bus configured to connect the first buffer and the second buffer,
wherein the first memory transfers a second clock to the second memory using the first clock,
the first buffer transfers data to the second memory in response to the first clock, and
the second buffer receives the data from the first buffer in response to the second clock.

2. The device of claim 1, wherein the first memory includes a delay circuit configured to generate the second clock by delaying the first clock.

3. The device of claim 1, further comprising a clock path configured to connect the first memory and the second memory.

4. The device of claim 1, further comprising a control circuit configured to generate an enable signal to assert the second clock,
wherein the second memory receives the first clock and switches between the first clock and the second clock based on the enable signal.

5. The device of claim 4, wherein the control circuit receives the second clock and generates the enable signal in response to the second clock.

6. The device of claim 5, further comprising a clock path configured to connect the first memory and the control circuit.

7. The device of claim 1, further comprising a generation circuit configured to generate the first clock.

8. The device of claim 1, further comprising:
a selector configured to select one of the second clock and a third clock from the second memory based on a control signal;
a first NAND gate having a first input terminal connected to a output terminal of the selector, a second input terminal for receiving the control signal, and a output terminal connected to the second buffer; and
a second NAND gate having a first input terminal connected to the output terminal of the selector, a second input terminal for receiving the control signal, and a output terminal connected to the first buffer.

9. The device of claim 8, wherein the second memory includes a delay circuit configured to generate the third clock by delaying the first clock.

10. The device of claim 8, further comprising a control circuit configured to generate the control signal.

11. A semiconductor memory device comprising:
a first memory configured to receive a first clock and including a first buffer configured to perform a data input operation and a data output operation;
an ECC circuit including a second buffer configured to perform a data input operation and a data output operation; and
a data bus configured to connect the memory and the ECC circuit,
wherein the first memory transfers a second clock to the ECC circuit using the first clock,
the first buffer transfers data to the ECC circuit in response to the first clock, and
the second buffer receives the data from the first buffer in response to the second clock.

12. The device of claim 11, wherein the first memory includes a delay circuit configured to generate the second clock by delaying the first clock.

13. The device of claim 11, further comprising a clock path configured to connect the first memory and the ECC circuit.

14. The device of claim 11, further comprising a control circuit configured to generate a control signal to control the ECC circuit.

15. The device of claim 14, wherein the control circuit receives the second clock and generates the control signal in response to the second clock.

16. The device of claim 15, further comprising a clock path configured to connect the first memory and the control circuit.

17. The device of claim 11, further comprising a generation circuit configured to generate the first clock.

18. The device of claim 11, further comprising:
a second memory configured to receive the first clock and including a second buffer configured to perform a data input operation and a data output operation;
a selector configured to select one of the second clock and a third clock from the second memory based on a control signal;
a first NAND gate having a first input terminal connected to a output terminal of the selector, a second input terminal for receiving the control signal, and a output terminal connected to the second buffer; and
a second NAND gate having a first input terminal connected to the output terminal of the selector, a second input terminal for receiving the control signal, and a output terminal connected to the first buffer.

19. The device of claim 18, wherein the second memory includes a delay circuit configured to generate the third clock by delaying the first clock.

20. The device of claim 18, further comprising a control circuit configured to generate the control signal.
